(19) United States
(12) Patent Application Publication
(10) Pub. No.: US 2026/0222699 A1
(43) Pub. Date: Jul. 30, 2026

(54) EVENT VISION SENSORS WITH DIGITAL EVENT DETECTION

(71) Applicant: OMNIVISION TECHNOLOGIES, INC., Santa Clara, CA (US)

(72) Inventors: Andreas Suess, San Jose, CA (US); Boyd Fowler, Sunnyvale, CA (US); Kenny Geng, Mountain View, CA (US)

(21) Appl. No.: 19/037,249

(22) Filed: Jan. 26, 2025

(51) Int. Cl. H04N 25/47; H03M 1/12; H04N 25/77; H04N 25/78; H04N 25/79

(52) U.S. Cl. CPC H04N 25/47; H03M 1/1245; H04N 25/77; H04N 25/78; H04N 25/79

(57) ABSTRACT

Event vision sensors with digital event detection are disclosed herein. In one embodiment, an image sensor includes an EVS pixel with a photosensor, an integrating-type photo-detecting stage, and in-pixel sampling circuitry including multiple circuit branches. An analog-to-digital converter (ADC) is coupled to the in-pixel sampling circuitry and converts analog irradiance levels into digital signals. Event detection circuitry coupled to the ADC computes event signals based on (i) temporal contrast differences between corresponding digital signals output by the ADC and (ii) a contrast threshold. The in-pixel sampling circuitry can include branches for sampling momentary integrated signal irradiance levels and integrated reference irradiance levels. The event detection circuitry can assert event signals when temporal contrast differences exceed the threshold, indicating event detection during an exposure period.

### TECHNICAL FIELD

This disclosure relates generally to image sensors. For example, several embodiments of the present technology are directed to event vision sensors and/or hybrid image sensors that employ EVS pixels and corresponding pixel-level or cluster-level analog-to-digital converters to facilitate digital event detection.

### BACKGROUND

Image sensors have become ubiquitous and are now widely used in digital cameras, cellular phones, security cameras, as well as medical, automobile, and other applications. As image sensors are integrated into a broader range of electronic devices, it is desirable to enhance their functionality, performance metrics, and the like in as many ways as possible (e.g., resolution, power consumption, dynamic range, etc.) through both device architecture design as well as image acquisition processing.

A typical image sensor operates in response to image light from an external scene being incident upon the image sensor. The image sensor includes an array of pixels having photosensitive elements (e.g., photodiodes) that absorb a portion of the incident image light and generate image charge upon absorption of the image light. The image charge photogenerated by the pixels may be measured as analog output image signals on column bitlines that vary as a function of the incident image light. In other words, the amount of image charge generated is proportional to the intensity of the image light, which can be read out as analog image signals from the column bitlines and converted to digital values to provide information that is representative of the external scene.

### BRIEF DESCRIPTION OF THE DRAWINGS

Non-limiting and non-exhaustive embodiments of the present technology are described below with reference to the following figures, in which like or similar reference numbers are used to refer to like or similar components throughout unless otherwise specified.

FIG. 1 is a partially schematic diagram of a stacked hybrid complementary metal oxide semiconductor (CMOS) image sensor (CIS) and event-based vision sensor (EVS) system, configured in accordance with various embodiments of the present technology.

FIG. 2 is a partially schematic circuit diagram of an EVS pixel configured in accordance with various embodiments of the present technology.

FIG. 3 is a partially schematic circuit diagram of an analog-to-digital converter and event detection circuitry, each configured in accordance with various embodiments of the present technology.

Skilled artisans will appreciate that elements in the figures are illustrated for simplicity and clarity and are not necessarily drawn to scale. For example, the dimensions of some of the elements in the figures may be exaggerated relative to other elements to aid in understanding of various aspects of the present technology. In addition, common but well-understood elements or methods that are useful or necessary in a commercially feasible embodiment are often not depicted in the figures, or described in detail below, to avoid unnecessarily obscuring the description of various aspects of the present technology.

### DETAILED DESCRIPTION

The present technology is generally directed to event vision sensors and hybrid image sensors. For example, several embodiments of the present technology discussed in detail below relate to event vision sensor (EVS) pixels that employ integrating-type photo-detecting stages and in-pixel sampling circuitry in combination with analog-to-digital converts to perform digital event detection. As a specific example, several EVS pixels described in greater detail below include two in-pixel sampling circuit branches: a first circuit branch for sampling a reference signal (e.g., an integrated reference irradiance level) and a second circuit branch for sampling a pixel signal (e.g., a momentary integrated signal irradiance level). The reference signal and the pixel signal are converted into digital signals by pixel-level, cluster-level, or peripheral level analog-to-digital converters. In turn, event detection circuitry (i) computes a difference between the digitized signals and (ii) compares the difference to a contrast threshold to detect events, performing all computations in the digital domain.

In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

Spatially relative terms (e.g., “beneath,” “below,” “over,” “under,” “above,” “upper,” “top,” “bottom,” “left,” “right,” “center,” “middle,” and the like) may be used herein for ease of description to describe one element’s or feature’s relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features may then be oriented “above” the one or more other elements or features. Thus, the exemplary terms “below” and “under” are non-limiting and can encompass both an orientation of above and below. The device or system may additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements may also be present.

Temporal relative terms such as “simultaneously,” “substantially simultaneously,” or “at the same time” are used herein to describe simultaneous performance or operation occurrence in a near instantaneous manner that takes into account necessary delays in signal transmission and/or processing, such as circuitry processing time, signal propagation time, computing time, or the like associated with circuit components. Thus, unless otherwise specified, “simultaneously,” “substantially simultaneously,” or “at the same time” as used herein may refer to events or operations that occur at the exact same time or within one second or less of each other after taking into account signal transmission and/or processing.

It will be understood that, although the terms first, second, third, etc., may be used in the disclosure and claims to describe various elements, these elements should not be limited by these terms and should not be used to determine the process sequence or formation order of associated elements. Unless otherwise indicated, these terms are merely used to distinguish one element from another element. Thus, a first element discussed below could be termed a second element without departing from the teachings of the disclosed embodiments. As another example, an element can be termed a “third element” to distinguish the element (e.g., for antecedent-basis purposes) from another element termed a “first element,” and without requiring the presence of a second element.

It is appreciated that the term "semiconductor material" recited throughout the disclosure may correspond to a part of or an entirety of a semiconductor wafer (e.g., a silicon wafer). In some embodiments, the semiconductor material may include or otherwise formed of silicon, a silicon germanium alloy, germanium, a silicon carbide alloy, an indium gallium arsenide alloy, any other alloys formed of III-V group compounds, combinations thereof, one or more epitaxial layers of the aforementioned materials, or a bulk substrate thereof. More specifically, semiconductor material may correspond to any semiconductor material or combination of materials that may be doped or otherwise configured to facilitate the formation of an integrated circuit (e.g., forming individual circuitry components such as source/drain regions of transistors, memory elements, photodiodes, or the like). It is appreciated that the term “photodiode” may correspond to a doped region disposed within the semiconductor material configured to photogenerate image charge(s) (e.g. , one or more electrons or holes) in response to incident light. For example, photodiode may correspond to an n-doped region disposed within a p-type semiconductor material or an n-doped region surrounded by a p-type well disposed within the semiconductor material.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

### A. Overview

An active pixel sensor employs an array of pixels that are used to capture intensity images/video of an external scene. More specifically, the pixels are used to obtain CIS information (e.g., intensity information) corresponding to light from the external scene that is incident on the pixels. CIS information obtained during an integration period is read out at the end of the integration period and used to generate a corresponding intensity image of the external scene.

In comparison, event vision sensors (e.g., event driven sensors or dynamic vision sensors) employ EVS pixels that are usable to obtain non-CIS information (e.g., contrast information, intensity changes, event data) corresponding to light from an external scene that is incident on those EVS pixels. Many event vision sensors read out an EVS pixel and/or convert a corresponding pixel signal into a digital signal only when the EVS pixel detects a change (e.g., an event) in the external scene. In other words, in most event vision sensors, EVS pixels that do not detect a change in the external scene are not read out and/or pixel signals corresponding to such EVS pixels are not converted into digital signals (thereby saving power). As a result, unlike active pixel sensors with synchronous integration times, these event vision sensors do not suffer from limited dynamic ranges and are able to accurately capture high-speed motion. Thus, these event visions sensors are often more robust than active pixel sensors in low lighting conditions and/or in highly dynamic scenes because they are not affected by under/over exposure or motion blur associated with a synchronous shutter. Stated another way, such event vision sensors can be used to provide ultra-high frame rates and to accurately capture high-speed motions.

Hybrid image sensors employ an array of pixels that includes a combination of (i) active (CIS) pixels usable to obtain CIS information corresponding to light from an external scene and (ii) EVS pixels usable to obtain non-CIS information corresponding to light from the external scene. Such hybrid image sensors are therefore able to simultaneously capture (a) intensity images/video of an external scene and (b) events occurring within the external scene.

An EVS pixel is commonly configured such that its output is used to yield specific values when log intensity of light incident on a photosensor of the pixel exceeds predefined thresholds. More specifically, an EVS pixel is often configured such that its output yields a +1 value when log intensity increases by an amount greater than a first predefined threshold, indicating that an UP event (e.g., light changing from darker to brighter and greater than the first predefined threshold) has been detected within an external scene. In addition, the EVS pixel is often configured such that its output yields a -1 value when log intensity decreases by an amount greater than a second predefined threshold, indicating that a DOWN event (e.g., light changing from brighter to darker and greater than the second predefined threshold) has been detected within the external scene. The output of the EVS pixel can be used to yield no value (e.g., a value equivalent to zero (0)) when changes in log intensity observed by the EVS pixel do not exceed the first or second predefined thresholds, indicating that neither an UP event nor a DOWN event have been detected in the external scene.

Such EVS pixels typically include per-pixel circuitry that receives photocurrent as input and communicates events with row/column peripheral readout circuitry. In particular, such EVS pixels typically employ an analog front-end circuit for detection of events from photocurrent changes. Use of an analog front-end circuit, however, is associated with several drawbacks. For example, analog front-end circuits continuously consume DC power. As another example, some dynamic behavior of the analog front-end circuits can be signal dependent, making the dynamic behavior susceptible to problems associated with slewing from source follower transistors, kick-back from reset operations, etc. As still another example, scalability of analog front-end circuits is limited by fixed pattern noise (FPN) requirements, including considerations for amplifier sizing and capacitance ratios.

To address these concerns, the present technology is generally directed to event vision sensors and hybrid imaging sensors with digital event detection. For example, several embodiments disclosed herein are directed to event vision sensors and/or hybrid image sensors that employ EVS pixels having integrating-type front-end circuits. The integrating-type front-end circuits are each configured to synchronously produce analog signals indicative of non-CIS information (e.g., contrast information, intensity changes, event data) corresponding to light from an external scene that is incident on a photosensor of the respective EVS pixel. Each integrating-type front-end circuit includes or is coupled to an analog-to-digital converter (ADC) that is configured to convert analog signals produced using the integrating-type front-end circuit into corresponding digital signals.

As a specific example, an EVS pixel of the present technology can include an integrating-type front-end circuit with two in-pixel sampling circuit branches: a first branch configured to produce an analog reference signal (e.g., an integrated reference irradiance level) and a second branch configured to produce an analog pixel signal (e.g., a momentary integrated signal level). Each branch can be coupled to an ADC, which can be configured to (a) convert the analog reference signal into a digital reference signal and/or (b) convert the analog pixel signal into a digital pixel signal. Continuing with this specific example, outputs of the ADC can be coupled to an event detection circuit configured to (i) determine a difference between the digital pixel signal and the digital reference signal and (ii) detect an event based on a comparison of the computed difference to a predefined threshold. In other words, event vision sensors, hybrid imaging sensors, and/or EVS pixels configured in accordance with various embodiments of the present technology are configured to fully or entirely perform difference computations and event detection in the digital domain.

In some embodiments, the ADC can be pixel-level ADC (e.g., as opposed to a column-level ADC). For example, the ADC can be positioned within (e.g., on a same die as) the EVS pixel, and/or the ADC can be dedicated to (e.g., correspond only to) a single/independent/unique EVS pixel. In other embodiments, the ADC can be a cluster-level ADC (e.g., as opposed to a column-level ADC). For example, the ADC can be shared by a group of two or more EVS pixels (e.g., of different rows and/or different columns).

Use of a pixel-level or cluster-level ADC to provide digital samples and use of an event detection circuit to compute differences and handle threshold comparisons entirely in the digital domain are expected to offer several advantages. For example, when latency requirements are low, part of a front-end circuit (e.g., the ADC) for one or more EVS pixels of the present technology can be powered down to reduce power consumption and/or conserve power. As another example, assuming that a small form factor ADC technology (e.g., ramp converters) is used, use of integrating-type front-end circuits with pixel-level or cluster-level ADCs is expected to improve scalability and help overcome latency bottlenecks. Furthermore, because EVS pixels configured in accordance with various embodiments of the present technology employ integrating-type front-end circuits with pixel-level or cluster-level ADCs, latency is expected to be determined by the exposure time and is no longer expected to be signal dependent.

### B. Selected Embodiments of Event Vision Sensors with Digital Event Detection, and Associated Systems, Devices, and Methods

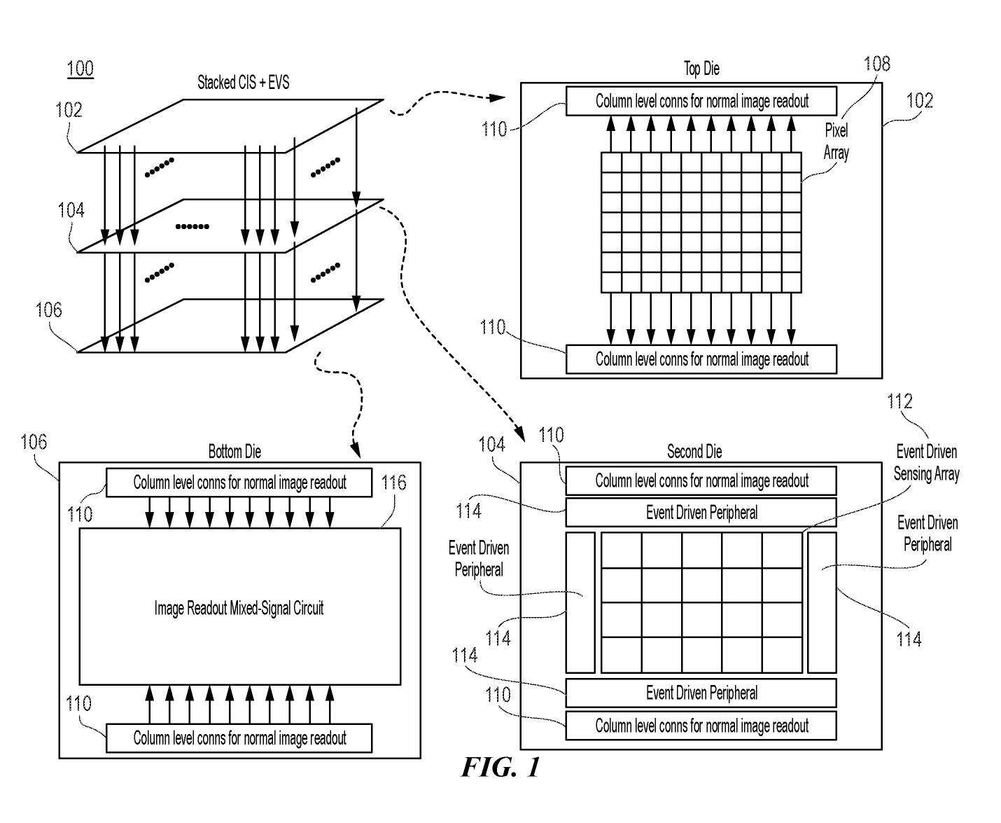

FIG. 1 is a partially schematic diagram of a stacked complementary metal oxide semiconductor (CMOS) image sensor (CIS) with an event-based vision sensor (EVS) system 100 (“the stacked system 100”), configured in accordance with various embodiments of the present technology. As shown, the stacked system 100 includes a first die 102, a second die 104, and a third die 106 that are stacked and coupled together in a stacked chip scheme. In some embodiments, the first die 102, the second die 104, and the third die 106 are semiconductor dies that include a suitable semiconductor material (e.g., silicon). In the illustrated embodiment, the first die 102 (also referred to herein as the “top die”) includes a pixel array 108. The third die 106 (also referred to herein as the “bottom die”) includes an image readout circuit 116 (also referred to herein as “image readout mixed-signal circuitry”). The image readout circuit 116 can be coupled to the pixel array 108 of the top die 102 through column level connections for normal image readout 110 (e.g., for intensity or luminance signal readout). In some embodiments, the column level connections for normal image readout 110 are implemented from column bitlines of the pixel array 108 with through silicon vias (TSVs) that extend between the top die 102 and the bottom die 106, and that are routed through the second die 104.

In some embodiments, the pixel array 108 is a two-dimensional (2D) array including a plurality of pixel cells (also referred to as “pixels” or as “pixel circuits”) that each includes at least one photosensor (e.g., at least one photodiode) exposed to incident light. As shown in the illustrated embodiment, the pixels are arranged into rows and columns. Pixels of the pixel array 108 can be operated at least partially as CIS pixels and/or at least partially as EVS pixels. When operated at least partially as CIS pixels, photosensors of the pixels can be used to acquire image data of an external scene (e.g., a person, place, object, etc., within the external scene) which can then be used to render images and/or video of the external scene. For example, each pixel, when at least partially operated in a CIS mode, can include one or more photosensors configured to photogenerate image charge in response to the incident light. After each pixel that is at least partially operated in a CIS mode has acquired its image charge, the corresponding analog image charge data can be read out by the image readout circuit 116 in the bottom die 106 through the column bit lines. In some embodiments, the image charge from each row of the pixel array 108 may be read out in parallel through column bit lines by the image readout circuit 116.

The image readout circuit 116 in the bottom die 106 can include amplifiers, analog to digital converter (ADC) circuitry, associated analog support circuitry, associated digital support circuitry, etc., for normal image readout and processing. In some embodiments, the image readout circuit 116 may also include event driven readout circuitry, which is described in greater detail below. In operation, the photogenerated analog image charge signals are read out from the pixel cells of pixel array 108, amplified, and converted to digital values in the image readout circuit 116. In some embodiments, image readout circuit 116 may read out a row of image data at a time. In other examples, the image readout circuit 116 may read out the image data using a variety of other techniques (not illustrated), such as a serial readout or a full parallel readout of all pixels simultaneously. The image data may be stored or even manipulated by applying post image effects (e.g., crop, rotate, remove red eye, adjust brightness, adjust contrast, and the like).

In the illustrated embodiment, the second die 104 (also referred to herein as the “middle die”) includes an event driven sensing array 112 that is coupled to the pixel array 108 in the top die 102. In some embodiments, the event driven sensing array 112 is coupled to the pixels of the pixel array 108 through hybrid bonds between the top die 102 and the middle die 104. The event driven sensing array 112 can include an array of event driven circuits. In some embodiments, each one of the event driven circuits in the event driven sensing array 112 is coupled to at least one of the plurality of pixels of the pixel array 108 through hybrid bonds between the top die 102 and the middle die 104 to synchronously detect events that occur in light that is incident upon the pixel array 108 in accordance with the teachings of the present disclosure.

In some embodiments, corresponding event detection signals are generated by the event driven circuits (e.g., integrating-type front-end circuits and/or analog-to-digital converters) in the event driven sensing array 112. The event detection signals can be received and processed by event driven peripheral circuitry 114 (e.g., event detection circuitry) that, in some embodiments, is arranged around the periphery of the event driven sensing array 112 in the middle die 104 (as is shown in FIG. 1) or is positioned in the bottom die 106. The embodiment illustrated in FIG. 1 also illustrates column level connections for normal image readout 110 that are routed through the middle die 104 between the top die 102 and the bottom die 106.

Although discussed above in the context of hybrid image sensors, EVS pixels of the present technology can alternatively be employed in event vision sensors that omit CIS pixels. In these embodiments, circuitry of the EVS pixels can be distributed across one or more dies. For example, photosensors, all or a subset of integrating-type photo-detecting stages, all or a subset of in-pixel sampling circuitry, all or a subset of ADCs, all or a subset of event detection circuitry, and/or all or a subset of reset circuitry can be co-located on a same die. Alternatively, photosensors can be positioned on a first (top) die; all or a subset of integrating-type photo-detecting stages of the EVS pixels can be positioned on the first die and/or on a second (bottom or middle) die; all or a subset of in-pixel sampling circuitry can be position on the first die and/or on a second (bottom or middle die); all or a subset of analog digital converters can be positioned on the first die, the second die, and/or a third (bottom) die; all or a subset of event detection circuitry can be positioned on the second die and/or the third die; and/or all or a subset reset circuitry can be positioned on the first die, the second die, and/or the third die. When distributed across multiple dies, the various circuitry can be connected using interconnect structures, such as TSVs, vias, hybrid bonds (e.g., pixel-level hybrid bonds), etc.

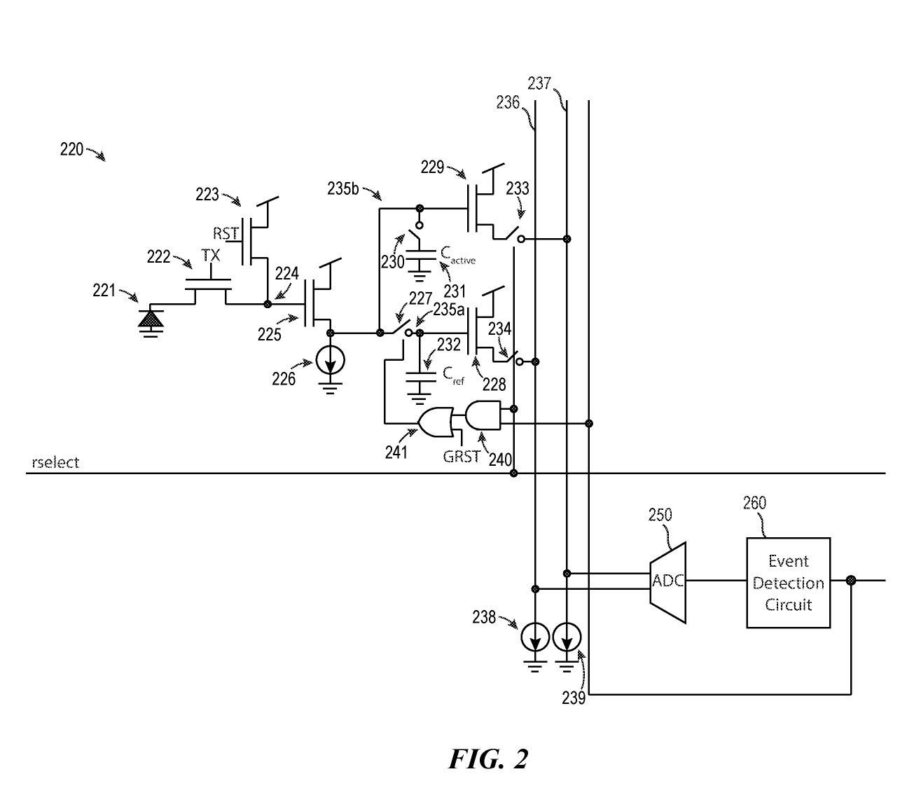

FIG. 2 is a partially schematic circuit diagram of an event vision sensor (EVS) pixel 220 configured in accordance with various embodiments of the present technology. The EVS pixel 220 can be an example of one of the pixels of the pixel array 108 of FIG. 1 or of other EVS pixels configured in accordance with various embodiments of the present technology. As shown, the EVS pixel 220 includes a photosensor 221, an integrating-type photo-detecting stage, in-pixel sampling circuitry, an analog-to-digital converter 250 ("ADC 250"), an event detection circuit 260, and reset circuitry. In the illustrated embodiment, the reset circuitry includes an AND logic gate 240 and an OR logic gate 241.

In some embodiments, the photosensor 221 includes a photodiode or another suitable type of photosensor. As a specific example, the photosensor 221 includes a pinned photodiode. In operation, the photosensor 221 is configured to photogenerate image charge based at least in part on light incident on the photosensor 221 from an external scene.

The integrating-type photo-detecting stage includes a transfer transistor 222 selectively coupling (and thereby selectively transferring image charge photogenerated by) the photosensor 221 to a floating diffusion 224 based at least in part on a transfer signal TX. The integrating-type photo-detecting stage further includes a reset transistor 223, a first source follower transistor 225. The reset transistor 223 is configured to selectively couple the floating diffusion 224 to a power supply voltage (and thereby reset a voltage at the floating diffusion 224) based at least in part on a reset signal RST. When the reset transistor 223 and the transfer transistor 222 are simultaneously in an activated state, the photosensor 221 can additionally be coupled to the power supply voltage via the transfer transistor 222 and the reset transistor 223.

The first source follower transistor 225 is coupled between the power supply voltage and ground, and includes a gate coupled to the floating diffusion 224. More specifically, the first source follower transistor 225 is coupled between the power supply and a first current source 226, and the first current source 226 is coupled between the first source follower transistor 225 and ground. The first source follower transistor 225 is configured to produce an analog voltage signal at its source based at least in part on a voltage at the floating diffusion 224 that is applied to the gate of the first source follower transistor 225.

As shown, the in-pixel sampling circuitry of the EVS pixel 220 includes a first switch 227, a first circuit branch 235a, and a second circuit branch 235b. As discussed in greater detail below, the first switch 227 is configured to selectively couple the first circuit branch 235a to the source of the first source follower transistor 225 based at least in part on an output of the reset circuitry, which corresponds to an output of the OR logic gate 241 in the illustrated embodiment. More specifically, the first circuit branch 235a includes a first capacitor 232 and a second source follower transistor 228, and the first switch 227 selectively couples (i) a first terminal (or plate) of the first capacitor 232 and a gate of the second source follower transistor 228 to (ii) the source of the first source follower transistor 225. The first terminal of the first capacitor 232 is coupled to the gate of the second source follower transistor 228, and a second terminal (or plate) of the first capacitor 232 is coupled to ground. The first capacitor 232 is illustrated with a first capacitance C_{ref}.

The second source follower transistor 228 is coupled between the power supply voltage and a third switch 234 that selectively couples a source of the second source follower transistor 228 to a first readout line 236. A second current source 238 is electrically positioned on the first readout line 236 between the third switch 234 and ground. As discussed in greater detail below, the first circuit branch 235a is configured as in-pixel sampling circuitry. More specifically, the first circuit branch 235a is configured to sample a reference voltage level (e.g., an integrated reference irradiance level) onto the first capacitor 232, and the second source follower transistor 228 is configured to produce a corresponding analog voltage signal at its source based at least in part on the reference voltage level applied to the gate of the second source follower transistor 228. In turn, the analog voltage signal produced by the second source follower transistor 228 can be selectively output onto the first readout line 236 via the third switch 234 and based at least in part on a row select signal rselect.

Referring now to the second circuit branch 235b, the second circuit branch 235b includes a third source follower transistor 229 that includes a gate coupled to the source of the first source follower transistor 225. In some embodiments, the second circuit branch 235b further includes (a) a second capacitor 231 and/or (b) a second switch 230 configured to selectively couple a first terminal (or plate) of the second capacitor 231 to the gate of the third source follower transistor 229 and to the source of the first source follower transistor 225. A second terminal (or plate) of the second capacitor 231 is coupled to ground. The second capacitor 231 is illustrated with a second capacitance C_{active}. The second capacitor 231 and the second switch 230 are optional and therefore can be omitted in other embodiments of the present technology.

The third source follower transistor 229 is coupled between the power supply voltage and a fourth switch 233 that selectively couples a source of the third source follower transistor 229 to a second readout line 237. A third current source 239 is electrically positioned on the second readout line 237 between the fourth switch 233 and ground. As discussed in greater detail below, the second circuit branch 235b is configured as in-pixel sampling circuitry. More specifically, the second circuit branch 235b is configured to sample a momentary voltage level (e.g., a momentary integrated signal level) onto the second capacitor 231, and/or the third source follower transistor 229 is configured to produce an analog voltage signal at its source based at least in part on the momentary voltage level applied to the gate of the third source follower transistor 229. In turn, the analog voltage signal produced by the third source follower transistor 229 can be selectively output onto the second readout line 237 via the fourth switch 233 and based at least in part on the row select signal rselect. Thus, the fourth switch 233 and the third switch 234 can be controlled using a same signal. In other embodiments, the fourth switch 233 and the third switch 234 can be controlled using different signals, such as to provide independent control of the fourth switch 233 and the third switch 234.

As shown in the illustrated embodiment, analog signals generated at the source of the second source follower transistor 228 and selectively output on the first readout line 236 via the third switch 234 can be fed into a first input of the ADC 250. Similarly, analog signals generated at the source of the third source follower transistor 229 and selectively output on the second readout line 237 via the fourth switch 233 can be fed into a second input of the ADC 250. In turn, the ADC 250 converts the analog signals received via the first and second readout lines 236, 237 into corresponding digital signals. In some embodiments, conversion of analog signals output onto the first and second readout lines 236, 237 into digital signals by the ADC 250 can be initiated based at least in part assertion of the row select signal rselect that is used to activate the third switch 234 and the fourth switch 233. Initiation of the conversion based on the row select signal rselect is expected to reduce power consumption and/or reserve power, as described in greater detail below. Digital signals output by the ADC 250 are then input into the event detection circuit 260 that is configured to determine whether the pixel 220 has detected an event based on light incident on the photosensor 221 (e.g., during an exposure period).

As discussed in greater detail below, when the event detection circuit 260 detects an event while the row select signal rselect is asserted, an output of the AND logic gate 240 can be asserted that in turn causes (i) an output of the OR logic gate 241 to be asserted and (ii) the first switch 227 to couple the first capacitor 232 to the source of the first source follower transistor 225. As a result, a voltage of on the first capacitor 232 follows the voltage at the source of the first source follower transistor 225 until the output of the OR logic gate 241 is de-asserted and the first switch 227 uncouples the first capacitor 232 from the source of the first source follower transistor 225. In some embodiments, as a result of the first switch 227 being turned on based at least in part on assertion of the output of the OR logic gate 241, the same or similar analog signals can appear on the first and second readout lines 236 and 237, which can (after conversion into corresponding digital signals by the ADC 250, comparison of the corresponding digital signals in the event detection circuit 260 to compute a difference between the corresponding digital signals, and comparison of the difference to a contrast threshold in the event detection circuit 260) de-assert (a) the event signal output by the event detection circuit 260, (b) the output of the AND logic gate 240, and (c) the output of the OR logic gate 241, thereby preparing the EVS pixel 220 to detect a next event. As shown in FIG. 2, the output of the OR logic gate 241 can also be asserted when a global reset signal GRST is asserted.

Although not shown in the illustrated embodiment, the EVS pixel 220 can include several components in addition to the components illustrated in FIG. 2. For example, the EVS pixel 220 can be configured as (and therefore include corresponding circuit components for) a high dynamic range (HDR) pixel. Additionally, or alternatively, the EVS pixel 220 can be configured as (and therefore include corresponding circuit components for) a dual conversion gain (DCG) pixel. In these and still other embodiments, the EVS pixel 220 can be configured as (and therefore include corresponding circuit components for) a lateral-overflow-integration-capacitor-type ("LOFIC-type") pixel. The DCG pixel and/or the LOFIC-type pixel can be achieved by selectively extending (or used to selectively extend) the charge capacity of the floating diffusion 224.

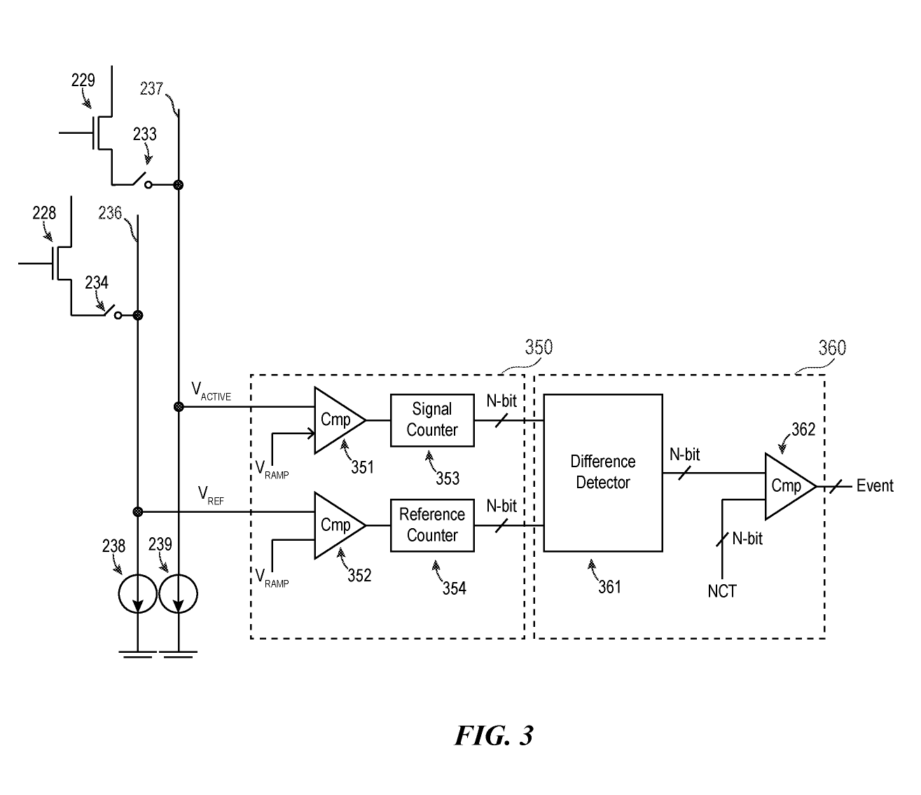

FIG. 3 is a partially schematic circuit diagram of an analog-to-digital converter 350 ("ADC 350") and an event detection circuit 360, each configured in accordance with various embodiments of the present technology. The ADC 350 can be an example of the ADC 250 of FIG. 2, and the event detection circuit 360 can be an example of the event detection circuit 260 of FIG. 2. Indeed, the ADC 350 and the event detection circuit 360 are illustrated in FIG. 3 as being coupled to the second source follower transistor 228, the third source follower transistor 229, the third switch 234, the fourth switch 233, the first readout line 236, the second readout line 237, the second current source 238, and the third current source 239 that were each discussed above with reference to FIG. 2. Alternatively, the ADC 350 and/or the event detection circuit 360 can be an example of other ADCs and/or other event detection circuitry, respectively, configured in accordance with various embodiments of the present technology.

Referring first to the ADC 350, the ADC 350 is illustrated with a first comparator 351, a second comparator 352, a first counter 353 (also referred to herein as a "signal counter" or a "first digital counter"), and a second counter 354 (also referred to herein as a "reference counter" or a "second digital counter"). The first comparator 351 includes a first input coupled to the second readout line 237 and configured to receive, via the fourth switch 233, an analog signal produced at the source of the third source follower transistor 229. The first comparator 351 further includes a second input configured to receive a ramp signal V_{RAMP}. Similarly, the second comparator 352 includes a first input coupled to the first readout line 236 and configured to receive, via the third switch 234, an analog signal produced at the source of the second source follower transistor 228. The second comparator 352 further includes a second input configured to receive the ramp signal V_{RAMP}.

In some embodiments, the ADC 350 can be configured as a ramp converter. For example, the first and second comparators 351, 352 can each be configured to compare a respective analog signal received at its first input to the analog ramp signal V_{RAMP} fed into its second input. The analog ramp signal V_{RAMP} fed into its second input can be based on a count maintained and incremented by the first counter 353 and/or the second counter 354. More specifically, when an analog signal is read onto the second readout line 237 via the fourth switch 233, the first counter 353 can begin incrementing a count up from zero, which can be converted into the analog ramp signal V_{RAMP} by a digital-to-analog converter (not shown). The analog ramp signal V_{RAMP} is ramped as the count increases. When the analog ramp signal V_{RAMP} is equal to or greater than the analog signal fed into the first input of the first comparator 351 via the second readout line 237, the output of the first comparator 351 flips and the first counter 353 stops counting. The digital output of the first counter 353 (e.g., an n-bit value) can be output and fed into a first input of the event detection circuit 360.

Similarly, when an analog signal is read onto the first readout line 236 via the third switch 234, the second counter 354 can begin incrementing a count up from zero, which can be converted into the analog ramp signal V_{RAMP} by a digital-to-analog converter (not shown). The analog ramp signal V_{RAMP} is ramped as the count increases. When the analog ramp signal V_{RAMP} is equal to or greater than the analog signal fed into the first input of the second comparator 352 via the first readout line 236, the output of the second comparator 352 flips and the second counter 354 stops counting. The digital output of the second counter 354 (e.g., an n-bit value) can be output and fed into a second input of the event detection circuit 360.

The ADC 350 may be implemented as a pixel-level ADC, a cluster-level ADC, or a peripheral-level ADC. When implemented as a pixel-level ADC, the ADC 350 can be dedicated to a single (e.g., only one) pixel, such as the EVS pixel 220 illustrated in FIG. 2. Thus, in some such implementations, each EVS pixel employed by a corresponding event vision sensor can include its own unique instance of the ADC 350. It is expected that use of pixel-level ADCs will enable fast, asynchronous readout.

When implemented as a cluster-level ADC, the ADC 350 can be shared amongst a group (or cluster) of EVS pixels (e.g., including the EVS pixel 220 of FIG. 2). The group of EVS pixels can include two or more EVS pixels arranged in different rows of a corresponding event driven sensing array. Additionally, or alternatively, the group of EVS pixels can include two or more EVS pixels arranged in different columns of a corresponding event driven sensing array. In some embodiments, when using cluster-level ADC, EVS pixels can be read out row-by-row during a preset evaluation period, with readout of each row being allocated a same amount of time. In some such embodiments, EVS pixel rows that do not include any EVS pixels that detected events can be skipped during the readout process. It is expected that use of pixel-level ADCs and/or cluster-level ADCs will facilitate achieving desired latency goals of approximately 100ns or less line-time.

When implemented as a peripheral-level ADC, the ADC 350 can be shared amongst all or large subsets of EVS pixels of a corresponding event driven sensing array. It is expected that use of a peripheral-level ADC may reduce or minimize EVS pixel footprint but at a cost of increased latency.

In some embodiments, the ADC 350 is configured with desired capabilities. For example, the ADC 350 can have a signal-to-noise ratio (SNR) rating of approximately 76dB and/or a 13-bit resolution in 100µs or less. Such a resolution is expected to handle a large dynamic range of input signals. In other embodiments, a smaller ADC resolution can be used for smaller dynamic ranges of input signals (e.g., that are achieved using exposure control techniques in combination with cluster-level or pixel-level ADCs). In these and still other embodiments, the ADC 350 can be a compressive or nonlinear ADC. As discussed above, the ADC 350 can be selectively powered down (e.g., during exposure/integration periods), such as to reduce power consumption and/or conserve power (e.g., in situations in which latency requirements are low). For example, the ADC 350 can be powered up and/or powered down (e.g., selectively powered on and/or selectively powered off) based at least in part on a row select signal (e.g., the row select signal rselect that is used to selectively activate the third switch 234 and the fourth switch 233, as discussed above with reference to FIG. 2). As a specific example, the ADC 350 can be powered down when the row select signal is not asserted (or is de-asserted), and/or the ADC 350 can be powered up when the row select signal is asserted. Stated another way, the ADC 350 can be powered down when the third switch 234 and the fourth switch 233 are deactivated or turned OFF, and/or the ADC 350 can be powered up when the third switch 234 and the fourth switch 233 are activated.

Referring now to the event detection circuit 360 of FIG. 3, the event detection circuit 360 includes a difference detector circuit 361 and a comparator 362. The difference detector circuit 361 includes a first input coupled to an output of the first counter 353 of the ADC 350 and a second input coupled to an output of the second counter 354 of the ADC 350. In operation, the difference detector is configured to (a) determine (e.g., compute) a difference between a first n-bit digital signal output from the first counter 353 and a second n-bit digital signal output form the second counter 354, and (b) feed the difference into a first input of the comparator 362. Thus, the difference detector circuit 361 can be a full adder, a full subtractor, a half subtractor, or another suitable type of circuit for computing a difference between the n-bit digital signals output from the ADC 350.

As shown, the comparator 362 receives, at its first input, the difference output by the difference detector circuit 361 as an n-bit digital signal. The comparator 362 further receives, at its second input, a nominal contrast threshold (NCT) as an n-bit digital signal. In some embodiments, the NCT corresponds to a (e.g., preset and/or programmable) contrast threshold value that provides a 50% fire probability for UP events and a 50% first probability for DOWN events. In the illustrated embodiment, the NCT is a unified NCT value that is used to detect both UP events and DOWN events. The comparator 362 is configured to (a) compare the difference received from the difference detector circuit 361 to the NCT and (b) assert an event signal Event output from the event detection circuit 360 when the difference is greater than or equal to the NCT. Assertion of the event signal Event can indicate an EVS pixel coupled to the event detection circuit 360 has detected an event in a monitored external scene. As discussed above, the asserted event signal Event can be passed to reset circuitry (e.g., an input of an AND logic gate) of the corresponding EVS pixel.

Although shown in FIG. 3 with a single (e.g., only one) instance of a difference detector circuit 361 and a single (e.g., only one) instance of a comparator 362, event detection circuits 360 of the present technology are not so limited. For example, in other embodiments, an event detection circuit can include multiple instances of difference detectors (similar to the difference detector circuit 361) and/or multiple instances of comparators (similar to the comparator 362). As a specific example, an event detection circuit of the present technology can include the difference detector circuit 361 and two instances of comparators (similar to the comparator 362 that each include an input coupled to the output of the difference detector circuit 361. Continuing with this example, the N-bit difference signal output from the difference detector circuit 361 can be fed into the first comparator for comparison to a first NCT signal, such as an NCT signal NCT_up used for detecting UP events (e.g., changes in contrast from darker to brighter). In addition, the N-bit difference signal output from the difference detector circuit 361 can be fed into the second comparator for comparison to a second NCT signal, such as an NCT signal NCT_dn used for detecting DOWN events (e.g., changes in contrast from brighter to darker). The first NCT signal and the second NCT signal can correspond to the same or different threshold values.

In some embodiments, the event detection circuit in the above example can be configured to output the output of the first comparator and the output of the second comparator as separate signals. This can enable downstream circuitry to determine whether the corresponding circuitry detected an UP event or a DOWN event. For example, when an output of the first comparator is asserted, this can indicate that the difference signal output from the difference detector circuit 361 was positive and/or had a magnitude greater than the first NCT signal (e.g., indicating detection of an UP event). As another example, when an output of the second comparator is asserted, this can indicate that the difference signal output from the difference detector circuit 361 was negative and/or had a magnitude greater than the second NCT signal (e.g., indicating detection of a DOWN event).

In these and other embodiments, the outputs of the first and second comparators can be combined, such as to control reset circuitry (e.g., the AND logic gate 240 and/or the OR logic gate 241 of FIG. 2) of the corresponding pixel. As a specific example, the event signal Event output from the event detection circuit can depend at least in part on the outputs of the first and second comparators. More specifically, the event signal Event output from the event detection circuit can be asserted when (a) the output of the first comparator is asserted (indicating that the difference signal output from the difference detector circuit 361 was positive and/or had a magnitude greater than the first NCT signal, which can indicate detection of an UP event) and/or (b) the output of the second comparator is asserted (indicating that the difference signal output from the difference detector circuit 361 was negative and/or had a magnitude greater than the second NCT signal, which can indicate detection of a DOWN event). In other words, the event signal Event can be asserted when either the output of the first comparator is asserted or the output of the second comparator is asserted. Thus, in some embodiments, the outputs of the first and second comparators can be fed into an OR logic gate (e.g., of the event detection circuit 360), and the output of the OR logic gate can be fed into an input of an AND logic gate (e.g., the AND logic gate 240 of FIG. 2) of reset circuitry of the corresponding pixel.

In some embodiments, the event detection circuit 360 can be configured as column-level circuitry. In other embodiments, the event detection circuit 360 can be configured as pixel-level circuitry (e.g., dedicated to a single or only one EVS pixel) or as cluster-level circuitry (e.g., dedicated to a group/cluster/subset of EVS pixels of a corresponding event driven sensing array.

Referring again to FIG. 2, a method of operating the EVS pixel 220 in combination with the ADC 250 and the event detection circuit 260 will now be described. The method may begin when either the global reset signal GRST is asserted or when both the row select signal rselect and the output of the event detection circuitry are asserted. Either of these conditions can cause the output of the OR logic gate 241 to be asserted, which may couple the first capacitor 232 and the gate of the second source follower transistor 228 to the source of the first source follower transistor 225 via the first switch 227.

The output of the OR logic gate 241 can remain asserted (and therefore the first capacitor 232 and the gate of the second source follower transistor 228 can remain coupled to the source of the first source follower transistor 225 via the first switch 227) for a period delta_t. During the period delta_t, voltage on the first capacitor 232 may follow the voltage at the source of the first source follower transistor 225, allowing a new analog reference charge Nref to accumulate on the first capacitor 232. In some embodiments, a voltage at the source of the first source follower transistor 225 can correspond to a voltage at the floating diffusion 224 following a reset of the floating diffusion 224 and/or the photosensor 221 using the reset transistor 223 and/or the transfer transistor 222.

After the period delta_t, the output of the OR logic gate 241 may be de-asserted, thereby opening the first switch 227 and decoupling the first capacitor 232 and the gate of the second source follower transistor 228 from the source of the first source follower transistor 225. This may sample an analog reference voltage level onto the first capacitor 232 of the first circuit branch 235a.

The second source follower transistor 228 can, based at least in part on the analog reference voltage signal sampled onto the first capacitor 232 and corresponding to the analog reference charge Nref, produce a corresponding analog reference signal (also referred to herein as an "integrated reference irradiance level") at the source of the second source follower transistor 228, which may be output onto the first readout line 236 via the third switch 234 when the row select signal rselect is asserted. The analog reference signal may be fed into the second input of the ADC 250 and converted into a second digital signal.

During an exposure period t, event charge N1 may be photogenerated by the photosensor 221 based on light from an external scene incident on the photosensor 221. The event charge N1 can be transferred via the transfer transistor 222 to—and accumulated at—the floating diffusion 224 during the exposure period t. This may produce a corresponding analog signal at the source of the first source follower transistor 225.

In some embodiments, the second switch 230 may be activated during the exposure period t, allowing a voltage on the second capacitor 231 to follow the voltage produced at the source of the first source follower transistor 225. Additionally, or alternatively, the voltage produced at the source of the first source follower transistor 225 may be applied to the gate of the third source follower transistor 229.

The third source follower transistor 229 can, based at least in part on the voltage applied to its gate corresponding to the event charge N1 accumulated at the floating diffusion 224, produce an analog pixel signal (also referred to herein as a "momentary integrated signal level") at the source of the third source follower transistor 229, which may be output onto the second readout line 237 via the fourth switch 233 when the row select signal rselect is asserted. The analog pixel signal may be fed into the first input of the ADC 350 and converted into a first digital signal.

Using the first and second digital signals output from the ADC 250, the event detection circuit 260 may then compare the first digital signal to the second digital signal and output a digital signal (also referred to herein as a "difference signal") indicative of the difference between the first and second digital signals. This comparison may be performed entirely in the digital domain.

Thereafter, the difference signal may be compared to a digital NCT signal corresponding to a nominal contrast threshold, which can be preset and/or programmable. In the event that the digital difference signal is less than or equal to the digital NCT signal, the output of the event detection circuit 260 may remain de-asserted, indicating that the EVS pixel 220 did not detect an event in the external scene during the exposure period t. In this case, the reference charge Nref may remain on the first capacitor 232 such that the second source follower transistor 228 continues to produce a same analog reference signal (integrated reference irradiance level) at the source of the second source follower transistor 228, at least until the EVS pixel 220 detects an event or the global reset signal GRST is asserted to assert the output of the OR logic gate 241.

On the other hand, in the event that the digital difference signal is greater than or equal to the digital NTC signal, the output of the event detection circuit 260 can be asserted, indicating that the EVS pixel 220 has detected an event during the exposure period t. The asserted output of the event detection circuit 260 may be fed back to the AND logic gate 240, thereby causing the output of the OR logic gate 241 to be asserted assuming that the row select signal rselect is also asserted. Assertion of the output of the OR logic gate 241 causes the first capacitor 232 and the gate of the second source follower transistor 228 to be coupled to the source of the first source follower transistor 225 via the first switch 227, thereby allowing (i) voltage on the first capacitor 232 to follow the voltage at the source of the first source follower transistor 225 and (ii) sampling of new analog reference charge Nref corresponding to a new period delta_t to accumulate on the first capacitor 232.

In this manner, the present technology facilitates computing event signals based on temporal contrast differences, with event detection (e.g., difference computations and/or threshold comparisons) handled entirely in the digital domain. The present technology also facilitates updating the integrated reference irradiance level when events are detected, thereby enabling EVS pixels to adapt to changing light conditions and detect subsequent events.

### C. Conclusion

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.” Also, the terms “connect” and “couple” are used interchangeably herein and refer to both direct and indirect connections or couplings. For example, where the context permits, element A “connected” or “coupled” to element B can refer (i) to A directly “connected” or directly “coupled” to B and/or (ii) to A indirectly “connected” or indirectly “coupled” to B.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

What is claimed is:

1. An image sensor, comprising:
an event vision sensor (EVS) pixel including a photosensor, an integrating-type photo-detecting stage, and in-pixel sampling circuitry including a plurality of circuit branches;
an analog-to-digital converter (ADC) coupled to the in-pixel sampling circuitry and configured to convert analog irradiance levels output by the in-pixel sampling circuitry into digital signals; and
event detection circuitry coupled to the ADC and configured to compute event signals based at least in part on (i) temporal contrast differences between corresponding digital signals output by the ADC and (ii) a contrast threshold.

2. The image sensor of claim 1, wherein the plurality of circuit branches includes a circuit branch configured to sample a momentary integrated signal irradiance level corresponding to image charge photogenerated by the photosensor during an exposure period.

3. The image sensor of claim 2, wherein the circuit branch is a first circuit branch, and wherein the plurality of circuit branches further includes a second circuit branch configured to sample an integrated reference irradiance level corresponding to the momentary integrated signal irradiance level.

4. The image sensor of claim 3, wherein:
the corresponding digital signals output by the ADC include a first digital signal corresponding to the momentary integrated signal irradiance level and a second digital signal corresponding to the integrated reference irradiance level; and
to compute an event signal, the event detection circuitry is configured to (a) compute a temporal contrast difference between the first and second digital signals output by the ADC and (b) compare the temporal contrast difference to the contrast threshold.

5. The image sensor of claim 4, wherein the event detection circuitry is configured to assert the event signal when the temporal contrast difference is greater than or equal to the contrast threshold, and wherein assertion of the event signal indicates the EVS pixel detected at least one event during the exposure period.

6. The image sensor of claim 5, wherein the image sensor further comprises reset circuitry configured to update the integrated reference irradiance level sampled by the second circuit branch upon detection of the event.

7. The image sensor of claim 6, wherein the reset circuitry is further configured to update the integrated reference irradiance level upon assertion of a global reset signal.

8. The image sensor of claim 4, wherein the second circuit branch is configured to maintain the integrated reference irradiance level in the event that the temporal contrast difference is less than or equal to the contrast threshold.

9. The image sensor of claim 1, wherein the ADC is a pixel-level ADC dedicated to the EVS pixel.

10. The image sensor of claim 1, wherein the ADC is a cluster-level ADC shared amongst a group of EVS pixels including the EVS pixel.

11. The image sensor of claim 1, wherein the photosensor is a pinned photodiode.

12. The image sensor of claim 1, wherein the integrating-type photo-detecting stage includes:
a floating diffusion;
a transfer transistor selectively coupling the photosensor to the floating diffusion;
a reset transistor selectively coupling the floating diffusion to a power supply voltage; and
a source follower transistor having a gate coupled to the floating diffusion.

13. The image sensor of claim 12, wherein:
the source follower transistor is a first source follower transistor and is configured to produce an analog voltage signal at its source based at least in part on a voltage at the floating diffusion; and
the plurality of circuit branches includes—
a first circuit branch having a second source follower transistor with a gate selectively coupled to the source of the first source follower transistor via a switch, and
a second circuit branch having a third source follower transistor different from the second source follower transistor and having a gate coupled to the source of the first source follower transistor.

14. A method of operating an image sensor, the method comprising:
sampling, during a first period of time, an integrated reference irradiance level using a first circuit branch of in-pixel sampling circuitry of an event vision sensor (EVS) pixel, wherein the integrated reference irradiance level is based at least in part on image charge accumulated at a floating diffusion of the EVS pixel during the first period of time using an integrating-type photo-detecting stage of the EVS pixel;
sampling, during a second period of time following the first period of time, a momentary integrated signal irradiance level using a second circuit branch of the in-pixel sampling circuitry of the EVS pixel, wherein the momentary integrated signal irradiance level is based at least in part on image charge accumulated at the floating diffusion of the EVS pixel during the second period of time using the integrating-type photo-detecting stage of the EVS pixel;
converting the momentary integrated signal irradiance level into a first digital signal;
converting the integrated reference irradiance level into a second digital signal; and
generating an event signal based at least in part on a difference between the first digital signal and the second digital signal.

15. The method of claim 14, wherein sampling the integrated reference irradiance level includes selectively coupling a capacitor of the first circuit branch to an output of the integrating-type photo-detecting stage for the first period of time.

16. The method of claim 14, wherein sampling the momentary integrated signal irradiance level includes selectively coupling a capacitor of the second circuit branch to an output of the integrating-type photo-detecting stage.

17. The method of claim 14, further comprising simultaneously reading out the integrated reference irradiance level from the first circuit branch and the momentary integrated signal irradiance level from the second circuit branch.

18. The method of claim 14, wherein converting the momentary integrated signal irradiance level and the integrated reference irradiance level into the first and second digital signals, respectively, includes converting the momentary integrated signal irradiance level and the integrated reference irradiance level into the first and second digital signals, respectively, using at least one pixel-level analog-to-digital converter that is dedicated to the EVS pixel.

19. The method of claim 14, wherein converting the momentary integrated signal irradiance level and the integrated reference irradiance level into the first and second digital signals, respectively, includes converting the momentary integrated signal irradiance level and the integrated reference irradiance level into the first and second digital signals, respectively, using at least one cluster-level analog-to-digital converter that is shared amongst a group of EVS pixels that includes the EVS pixel.

20. The method of claim 14, wherein generating the event signal based at least in part on the difference between the first digital signal and the second digital signal includes:
computing a difference between the first digital signal and the second digital signal; and
comparing a digital difference signal indicative of the difference to a digital contrast threshold signal indicative of a contrast threshold.

21. The method of claim 20, wherein:
generating the event signal further includes, in response to determining that the digital difference signal is greater than or equal to the digital contrast threshold signal, outputting the event signal in an asserted state; and
the method further comprises, based at least in part on the asserted event signal, sampling, during a third period of time, a new integrated reference irradiance level using the first circuit branch, wherein the new integrated reference irradiance level is based at least in part on image charge accumulated at the floating diffusion of the EVS pixel during the third period of time using the integrating-type photo-detecting stage of the EVS pixel.

22. The method of claim 20, wherein:
generating the event signal further includes, in response to determining that the digital difference signal is less than or equal to the digital contrast threshold signal, outputting the event signal in a de-asserted state; and
the method further comprises, based at least in part on the de-asserted event signal, maintaining the integrated reference irradiance level on the first circuit branch of in-pixel sampling circuitry.

23. An event vision sensor (EVS) pixel, comprising:
a photosensor configured to photogenerate image charge in response to light incident on the photosensor;
an integrating-type photo-detecting stage coupled to the photosensor; and
in-pixel sampling circuitry including a first circuit branch configured to sample an integrated reference irradiance level and a second circuit branch configured to sample a momentary integrated signal level.

24. The EVS pixel of claim 23, wherein the integrating-type photo-detecting stage includes a floating diffusion, a reset transistor configured to selectively couple the floating diffusion to a power supply voltage, and a source follower transistor having a gate coupled to the floating diffusion.

25. The EVS pixel of claim 24, wherein the integrating-type photo-detecting stage further includes a transfer transistor configured to selectively couple the photosensor to the floating diffusion.

26. The EVS pixel of claim 23, wherein the first circuit branch includes a capacitor and a source follower transistor having a gate coupled to a first terminal of the capacitor, wherein a second terminal of the capacitor is coupled to ground, and wherein the EVS pixel further comprises a switch configured to selectively couple the first terminal of the capacitor and the gate of the source follower transistor to an output of the integrating-type photo-detecting stage.

27. The EVS pixel of claim 26, wherein the switch is controllable via reset circuitry such that the switch is activated when (a) a global reset signal is asserted, (b) the EVS pixel detects an event, or (c) a combination thereof.

28. The EVS pixel of claim 23, wherein the second circuit branch includes a source follower transistor having a gate coupled to an output of the integrating-type photo-detecting stage.

29. The EVS pixel of claim 28, wherein the second circuit branch further includes a capacitor and a switch selectively coupling a first terminal of the capacitor to the gate of the source follower transistor and to the output of the integrating-type photo-detecting stage, and wherein a second terminal of the capacitor is coupled to ground.

30. The EVS pixel of claim 23, further comprising a pixel-level analog-to-digital converter that is coupled to the first circuit branch and the second circuit branch and is configured to convert the momentary integrated signal level and the integrated reference irradiance level into a first digital signal and a second digital signal, respectively.
